(19) United States
(12) Patent Application Publication
(10) Pub. No.: US 2004/0211594 A1
(43) Pub. Date: Oct. 28, 2004

(54) Vertical routing structure

(76) Inventors: Kwun-Yao Ho, Hsin-Tien City (TW); Moriss Kung, Hsin-Tien City (TW)

Correspondence Address: J.C. Patents, Inc., Suite 250, 4 Venture, Irvine, CA, 92618, US

(21) Appl. No.: 10/737,412

(22) Filed: Dec. 15, 2003

(30) Foreign Application Priority Data
Apr. 23, 2003 (TW) 92109449

(51) Int. Cl. H05K 1/11; H05K 3/42

(52) U.S. Cl. 174/264; 29/852; 174/257

(57) ABSTRACT

A vertical routing structure for a multi-layered substrate having a lamination structure therein. The lamination structure has at least a through hole that links up both surfaces of the lamination structure. The vertical routing structure comprises a conductive rod and a conductive layer. The conductive rod is formed inside the through-hole with the ends protruding above the respective upper and lower surface of the lamination structure. The conductive layer is positioned in the space between the interior sidewall of the through-hole and the conductive rod. The vertical routing structure on the substrate is able to reduce the area for laying the required circuits or increase the wiring density in a given area.

### CROSS-REFERENCE TO RELATED APPLICATION

This application claims the priority benefit of Taiwan application serial no. 92109449, filed on Apr. 23, 2003.

### BACKGROUND OF THE INVENTION

1. Field of Invention

The present invention relates to a routing structure. More particularly, the present invention relates to a vertical routing structure within a multi-layered substrate.

2. Description of Related Art

Following the rapid progress in electronic technologies in recent years, many personalized and multi-functional high-tech products have been developed. Many of these products are light, compact and slim to facilitate handling. At present, substrate type carrier is one of the most commonly used package elements in the fabrication of semiconductor devices. Substrate type carrier mainly includes those substrates that are fabricated by performing a laminate or a build-up process. Each substrate comprises a multiple of patterned circuit layers and a multiple of dielectric layers alternately laid over each other. Because each substrate contains finely distributed, precisely assembled and highly efficient wiring, these types of substrates are commonly used for fabricating flip chip packages.

In general, the patterned circuit layer in the substrate is formed by performing photolithographic and etching processes on a copper foil and the dielectric layer is formed by depositing dielectric material between neighboring patterned circuit layers. Electrical connection between neighboring patterned circuit layers is made through a plated through hole (PTH) or a conductive via. The dielectric layer is fabricated using a material including, for example, glass epoxy resin (FR-4, FR-5), bismaleimide-triazine (BT) or epoxy resin. In addition, the outermost layer of most substrates is often covered with as solder mask so that only the bonding pads on the substrate are exposed. The bonding pads may serve as contacts for connecting the substrate with an external device or the surface of the bonding pads may contain a pre-solder block to serve as a contact for bonding with a chip in a flip chip package.

FIG. 1 is a schematic cross-sectional view showing the routing structure inside a portion of the substrate fabricated through a build-up method. As shown in FIG. 1, a substrate having four circuit layers altogether is used as an example. The interior of the substrate 100 has an dielectric core layer 110. Non-patterned first circuit layers 120a, 120b are formed on the top and bottom surface of the core dielectric layer 110 respectively. Thereafter, the first circuit layers 120a, 120b are patterned to form patterned first circuit layers 120a, 120b. A mechanical drilling method is then used to form a plurality of through-holes 112 through the dielectric core layer 110. A conductive layer 115 is formed on the interior sidewalls of the through-holes 112, for example, by electroplating. A resinous material 114 is poured into the through-holes 112 so that the interior space of the through-holes 112 is filled to form a plurality of plated through holes 116 (only one is shown). Afterwards, other steps in the build-up method are carried out. Here, the steps for fabricating the layers on top of the core dielectric core layer 110 are illustrated as an example. First, a dielectric layer 130a is formed over the first circuit layer 120a. Thereafter, using either a photo via or a laser ablation method, the dielectric layer 130a is patterned to form a plurality of openings 132 (only one is shown) in the dielectric layer 130a. Conductive material is deposited into each opening 132 to form a plurality of conductive vias 134. A patterned second circuit layer 120c is formed over the dielectric layer 130a. The second circuit layer 120c and the first circuit layer 120a are electrically connected through the conductive via 134. Furthermore, the second circuit layer 120c has a plurality of bonding pads 122a thereon exposed through the outermost mask layer 150a. In addition, a pre-solder block 124 may be attached to the bonding pads 122a on the upper surface of the substrate 100 to serve as a contact for bonding with a chip in a flip chip package. Similarly, a dielectric layer 130b, a patterned second circuit layer 120d and a mask layer 150b can also be sequentially formed on the lower half of the dielectric core layer 110. Various types of contacts 126 including solder balls, pins or conductive blocks may be attached to the bonding pads 122b at the bottom surface of the substrate 100. Moreover, the contacts 126 can be arranged to form an area array on the undersurface of the substrate 100 so that a high-pin-count package substrate is produced.

Although a substrate fabricated using the conventional build-up method can be used to form a flip chip package with a high pin count, some drawbacks are often encountered during fabrication. Major drawbacks include: (1) the production cost for fabricating the plated through holes and the conductive vias is high because the processing steps are complicated; (2) the routing design of the plated through holes and the conductive vias prevents any reduction of the horizontal wiring area, that is, increasing the wiring density in the substrate is difficult; and (3) a larger alignment window must be set aside for patterning out the bonding pads on the second circuit layer through a photolithographic process so that the available wiring space within neighboring circuit traces is reduced.

### SUMMARY OF THE INVENTION

Accordingly, one object of the present invention is to provide a vertical routing structure for increasing the wiring density of inside a multi-layered substrate so that the average signal transmission path is reduced and the overall heat-dissipating capacity of the substrate is increased.

A second object of this invention is to provide a vertical routing structure for a multi-layered substrate with a high-density wiring layout such that the substrate has a plurality of mechanically drilled or laser ablation through-holes passing through the substrate for housing a conductive rod and a conductive layer. Furthermore, one end of the conductive rod protrudes above the upper surface of the substrate for directly bonding with a bump on a chip to form a flip chip package and the other end of the conductive rod bonds directly with a contact on the bottom surface of the substrate.

To achieve these and other advantages and in accordance with the purpose of the invention, as embodied and broadly described herein, the invention provides a vertical routing structure for a multi-layered substrate. The multi-layered substrate has a lamination structure with at least a through-hole linking up the two surfaces of the lamination structure. The vertical routing structure comprises a conductive rod and a conductive layer. The conductive rod is set up within the through hole, and both ends of the conductive rod protrude above the two surfaces of the lamination structure respectively. The conductive layer is positioned between the interior sidewall of the through hole and the outer surface of the conductive rod.

This invention also provides a method of fabricating a vertical routing structure within a multi-layered substrate. The multi-layered substrate has a lamination structure. The vertical routing structure is fabricated by performing at least the following operations: (a) form at least a through hole in the lamination structure, wherein the through hole passes through the lamination structure to linking up the two side surfaces; (b) form a conductive layer over the interior sidewall of the through-hole; and (c) fill up the through hole with a conductive material to form a conductive rod inside the through-hole such that both ends of the conductive rod protrudes above the two side surfaces of the lamination structure and the conductive layer occupies the space between the interior sidewall of the through hole and the outer surface of the conductive rod.

The vertical routing structure of this invention simplifies the conventional process of forming a plated through hole and conductive via and reduces the overall production cost of the substrate. In addition, for the same wiring density, the substrate with the vertical routing structure of this invention requires a smaller layout area. In other words, more wires can be laid on a substrate of a given surface area. Furthermore, one end of the conductive rod and the bump on a chip may be bonded together directly to form a flip chip package while the other end of the conductive rod may join up with a contact at the bottom surface of the substrate directly. Moreover, the conductive rod may serve as a thermal conduit to conduct heat away from the substrate.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view showing the routing structure inside a portion of the substrate fabricated through a build-up method.

FIG. 2A is a schematic cross-sectional diagram of a routing structure within a substrate according to one preferred embodiment of this invention.

FIG. 2B is a schematic cross-sectional diagram of another routing structure within a substrate according to one preferred embodiment of this invention.

FIG. 2C is a schematic cross-sectional diagram of yet another routing structure within a substrate according to one preferred embodiment of this invention.

FIG. 3 is a schematic cross-section diagram showing both the vertical routing structures in FIGS. 2A and 2B within a substrate according to this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

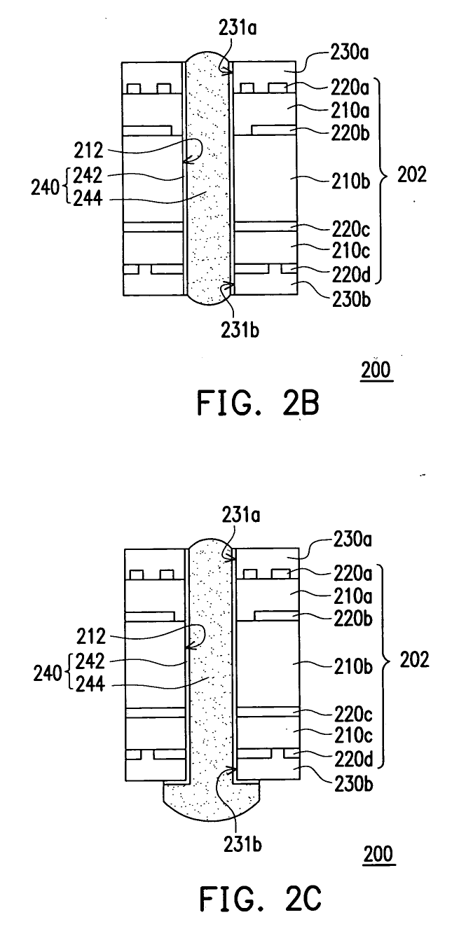

FIG. 2A is a schematic cross-sectional diagram of a routing structure within a substrate according to one preferred embodiment of this invention. The vertical routing structure is used in a multi-layered substrate. In particular, the vertical routing structure is applied to a multi-layered substrate with high-density wiring such as a carrier for joining with a flip chip or a general-purpose printed circuit board. In this embodiment, a substrate 200 having four wiring layers is used as an example. However, a substrate with any number of wiring layers greater than two is applicable. As shown in FIG. 2A, the multi-layered substrate 200 comprises a plurality of dielectric layers 210a, 210b, 210c and a plurality of patterned circuit layers 220a, 220b, 220c, 220d alternately positioned over each other. A build-up method can be used to form the dielectric layers 210a, 210b, 210c and the circuit layers 220a, 220b, 220c, 220d alternately over each other. Otherwise, a conventional lamination method can be used to form a lamination structure 202 comprising alternately positioned dielectric layers 210a, 210b, 210c and patterned circuit layers 220a, 220b, 220c, 220d in a single lamination operation. Note that mask layers (or a dielectric layer) 230a, 230b cover the outermost surfaces of the substrate 200 after forming the lamination structure 202. The mask layers 230a, 230b cover the outermost conductive layers 220a, 220d respectively. Furthermore, the mask layers 230a, 230b can be used to pattern out the locations of contacts on the outer conductive layers 220a and 220d by performing photolithographic and etching processes or performing a printing operation. The lamination structure 202 within the substrate 200 furthermore has a vertical routing structure 240 that passes through the substrate 200 vertically. The vertical routing structure connects electrically with the circuit layers 220c, 220d within the lamination structure 202, for example.

After forming the mask layers 230a, 230b, a plurality of through-holes 212 are formed in the lamination structure 202 of the substrate 200 by performing a mechanical or a laser drill. Since mechanical or laser drilling is a low-cost high-precision process, a through-hole 212 with a diameter within the range 50 to 100 μm can be obtained. Therefore, the vertically drilled through-hole 212 is able to serve as a space for accommodating the vertical routing structure 240. In fact, the through-hole 212 passes through the lamination structure 202 with the interior sidewall of the through-hole 212 linking the top and the bottom surface of the lamination structure 202. Thereafter, a conductive layer 242 is formed on the interior sidewall of the through-hole 212 by performing a plating operation. Conductive material that fills up the through hole 212 is subsequently deposited to form a conductive rod 244. The upper end and the lower end of the conductive rod 244 protrude beyond the top and bottom surface of the lamination structure 202 or even the mask layer (or dielectric layer) 230a, 230b to form the vertical routing structure 240.

In the process of forming the through-holes 212, a plurality of openings 231a (only one is shown) is directly formed in the mask layer 230a. Similarly, a plurality of openings 231b (only one is shown) is directly formed in the mask layer 230b. The ends of the conductive rod 244 completely fill the openings 231a and 231b and protrude above the surface of the mask layers 230a and 230b respectively. To form a contact with a larger area at the bottom end of the conductive rod 244, the mask layer 230b is patterned to form an opening 231b having a diameter greater than the through-hole 212 before forming the through-hole 212. Alternatively, the diameter of the opening 231b is enlarged after the through-hole 212 and the opening 231b is formed. In addition, the ends of each conductive rod 244 may serve directly as a bump, a pre-solder block or a solder ball. Alternatively, the ends of each conductive rod 244 may attach to a bump, a pre-solder block or a solder ball to serve as contact for connecting the substrate 200 with an external device.

FIG. 2B is a schematic cross-sectional diagram of another routing structure within a substrate according to one preferred embodiment of this invention. A contact may not be required at the bottom surface of the lamination structure 202. When this is the case, the opening 231b in the mask layer 230b can have a diameter identical to the through-hole 212 as shown in FIG. 2B. In other words, there is no need to enlarge the diameter of the opening 231b either before or after forming the through-hole 212.

FIG. 2C is a schematic cross-sectional diagram of yet another routing structure within a substrate according to one preferred embodiment of this invention. A bump contact having a larger spatial occupation is sometimes required at the bottom surface of the lamination structure 202. In this case, a portion of the conductive rod 244 may extend beyond the outer surface of the mask layer 230b to cover the exposed conductive layer 242 and produce a contact with a greater volume as shown in FIG. 2C. Alternatively, a solder ball or contact of some other shapes may be attached to the bottom end of the conductive rod 244 to enlarge the volume of the contact.

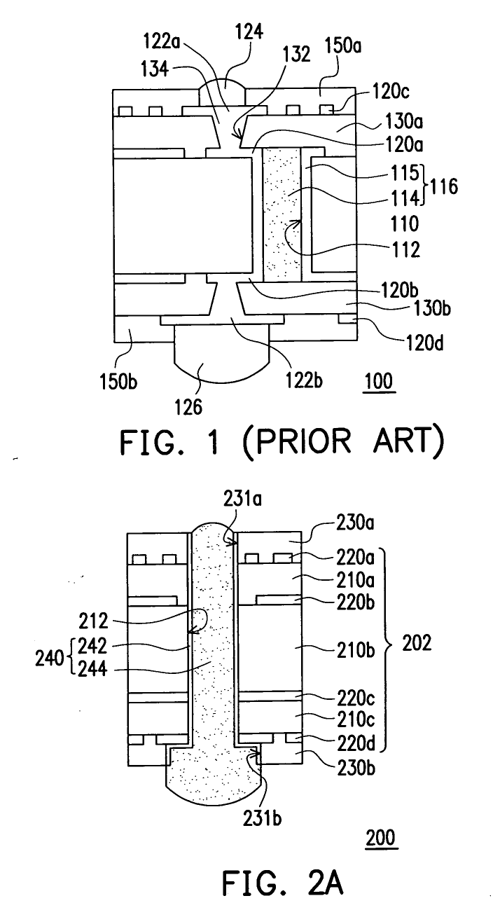

As shown in FIG. 2A, the method of this invention includes the following steps. First, the lamination structure 202 and the mask layers 230a, 230b are formed to produce the substrate 200. Thereafter, a mechanically or laser drilling operation is performed to produce a plurality of vertical through-holes 212 in the substrate 200. Finally, a vertical routing structure 240 is formed inside the lamination structure 202. Hence, the vertical routing structure 240 is less complicated to fabricate compared with the conventional method of forming the plated through-holes 114 and the conductive vias 134 as shown in FIG. 1. Thus, using the method of this invention to form the vertical routing structure 240 in the substrate 200 can save a lot of steps and reduce the overall production cost considerably.

The vertical routing structure 240 as shown in FIG. 2A mainly comprises a conductive rod 244 and a conductive layer 242. The conductive rod 244 is positioned within a through-hole 212 while the conductive layer 242 is positioned between the interior sidewall of the through hole 212 and the outer surface of the conductive rod 244. In addition, the conductive layer 242 and the patterned circuit layers 220c, 220d in the lamination structure 202 are electrically connected. In other words, the stacked circuit layers 220c, 220d are electrically connected through the vertical routing structure 240. Furthermore, the conductive rod 244 is fabricated using a material having an affinity for the conductive layer 242 including, for example, solder, low melting point alloy or metal. For example, if the conductive rod 244 is fabricated using lead-tin alloy, the conductive layer 242 is fabricated using copper. In general, conductive material in the liquid state is drawn into the through-hole 212 due to capillary effect so that a conductive rod 244 is formed after solidification. The method of filling the through-hole 212 with conductive material includes wave soldering, spraying, plating or dipping. When the wave soldering method is used to fill through-hole 212, external fluid motion can be utilized to remove any redundant conductive material away from the ends of the through-hole 212 so that residual conductive material will not stick together to result an electrical connection between neighboring conductive rods 244.

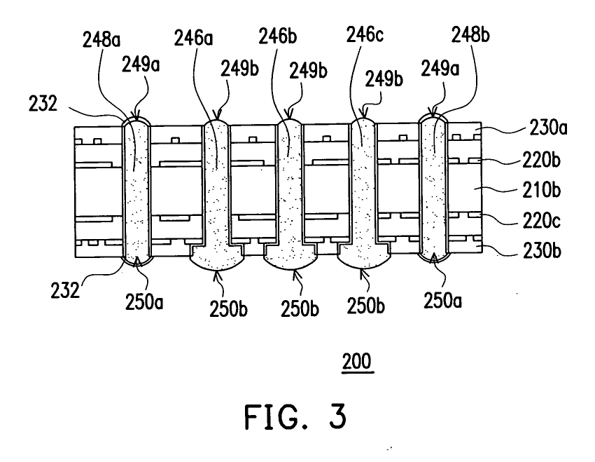

FIG. 3 is a schematic cross-section diagram showing both the vertical routing structures in FIGS. 2A and 2B within a substrate according to this invention. As shown in FIG. 3, both ends of the conductive rods 246a, 246b, 246c, 248a, 248b stick out of the outer surfaces of the mask layers 230a and 230b to serve as contacts for connecting the substrate 200 with external devices. The top end 249b of the conductive rods 246a, 246b, 246c may serve as a bump or pre-solder block for bonding with a flip chip. The bottom end 250b of the conductive rods 246a, 246b, 246c may serve as a contact for connecting directly with a solder ball, a pin or a conductive bump. Shape and size of the bottom end 250b of the conductive rods 246a, 246b, 246c are subjected to the control of the opening 231 in the mask layer 230b and the conductive layer 220d. In addition, the ends of a few conductive rods that have no need for further attachment such as the top end 249a and the bottom end 250a of the conductive rods 248a and 248b may be selectively covered with a protective layer 232. The protective layer 232 is fabricated using a material identical to the mask layer 230 or some other protective material. However, it is not an absolute requirement to form a protective layer 232 over the ends of such conductive rods (refer to the bottom end of the conductive rod 244 in FIG. 2B). Nevertheless, the protective layer 232 covered conductive rod 248b may still connect electrically with the circuit layers 220b, 220c, 220d and form a buried vertical routing structure inside the substrate 200.

As shown in FIG. 3, the conductive rods 246a, 246b, 246c, 248a, 248b all pass through the substrate 200. Thus, when the substrate 200 is used to form a flip chip package, any heat generated by a chip (not shown) can be conducted away through the conductive rods 246a, 246b, 246c, 248a, 248b. Moreover, the cross-sectional area of the conductive rods 246a, 246b, 246c, 248a, 248b is smaller than a conventional bonding pad 142. Hence, there is no need to provide additional spatial tolerance for possible misalignment in the process of patterning out the bonding pads 142 using the photolithographic process when the conductive rods are fabricated. That means, the area on the substrate 200 for laying down wires can be reduced for a given wiring density or the wiring density within the substrate 200 can be increased for the same layout area.

In summary, the major advantages of the vertical routing structure according to this invention includes:

1. The vertical routing structures inside the substrate are fabricated using relatively simple processes. Unlike a substrate fabricated using a conventional built-up method with lots of processing steps, the total number of processing steps is few so that the overall production cost of the substrate is reduced.

2. A mechanical or laser drilling method can be used to form the through-holes in the substrate. Thereafter, conductive material fills the through-holes to form the conductive rods. With this method of fabrication, the conductive rods occupy a very small horizontal area. Thus, the substrate can have a higher wiring density.

3. Unlike a convention fabrication method, there is no need to form a bonding pad for attaching a flip chip bump or a pre-solder block. Hence, forming the vertical routing structures in the substrate according to this invention permits an increase in the wiring density.

4. Since all the conductive rods of the vertical routing structures pass through the substrate and the conductive rods are fabricated from a thermally conductive material, the conductive rods may serve as a conduit for channeling heat away from a heat-generating device. Hence, the vertical routing structure has a greater heat-dissipating efficiency compared to a conventional plated through-hole.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A vertical routing structure for a multi-layered substrate with a lamination structure, wherein the lamination structure has at least a through-hole linking the two surfaces of the lamination structure, the vertical routing structure comprising:
a conductive rod positioned inside the through-hole and both ends of the conductive rod protruding above the two surfaces of the lamination structure respectively; and
a conductive layer formed between the interior sidewall of the through-hole and the conductive rod.

2. The vertical routing structure of claim 1, wherein the multi-layered substrate furthermore comprises a first mask layer having at least a first opening on one surface of the lamination structure and a second mask layer having at least a second opening on another surface of the lamination structure such that the ends of the conductive rod not only fill up the first opening and the second opening but also protrude beyond the surfaces of the first mask layer and the second mask layer respectively.

3. The vertical routing structure of claim 2, wherein the second opening has a diameter greater than the through-hole.

4. The vertical routing structure of claim 1, wherein one end of the conductive rods serves as a bump, a pre-solder block or a contact.

5. The vertical routing structure of claim 1, wherein the structure furthermore comprises a bump attached to one end of the conductive rod.

6. The vertical routing structure of claim 1, wherein the structure furthermore comprises a pre-solder block attached to one end of the conductive rod.

7. The vertical routing structure of claim 1, wherein the structure furthermore comprises a solder ball attached to one end of the conductive rod.

8. The vertical routing structure of claim 1, wherein the lamination structure furthermore comprises at least a buried circuit layer that connects electrically with the conductive layer.

9. A method of fabricating a vertical routing structure inside a multi-layered substrate having a lamination structure therein, the method comprising the steps of:
(a) forming at least a through-hole in the lamination structure, wherein the through-hole passes through the lamination structure to link up the upper and lower surface of the lamination structure;
(b) forming a conductive layer on the interior sidewall of the through-hole; and
(c) filling the through-hole with a conductive material to form a conductive rod inside the through-hole such that the ends of the conductive rods protrude above the respective surfaces of the lamination structure, and the conductive layer is positioned between the interior sidewall of the through-hole and the conductive rod.

10. The method of claim 9, wherein before performing step (a), a first mask layer and a second mask layer are formed on the respective surfaces of the lamination structure, during step (a), the through-hole passes through the first mask layer and the second mask layer so that a first opening is formed in the first mask layer and a second opening is formed in the second mask layer, and during step (b), the conductive layer is formed inside the first opening and the second opening, and during step (c), the two ends of the conductive rods not only completely fill the first opening and the second opening but also protrude beyond the surfaces of the first mask layer and the second mask layer respectively.

11. The method of claim 9, wherein before performing the step (a), a first mask layer and a patterned second mask layer are formed on the two surfaces of the lamination structure such that the second mask layer has a second opening, and during the step (a), the through-hole passes through the first mask layer and the second opening of the second mask layer so that a first opening is formed in the first mask layer, and during step (b), the conductive layer is formed inside the first opening and the second opening, and during step (c), the ends of the conductive rod not only fill up the first opening and the second opening respectively but also protrude beyond the surface of the first mask layer and the second mask layer respectively.

12. The method of claim 9, further comprising attaching a bump to one end of the conductive rod.

13. The method of claim 9, further comprising attaching a pre-solder block to one end of the conductive rod.

14. The method of claim 9, further comprising attaching a solder ball to one end of the conductive rod.

15. The method of claim 9, wherein the lamination structure furthermore comprises at least a buried circuit layer that connects electrically with the conductive layer.

16. The method of claim 9, wherein the step of filling the through hole with a conductive material in step (c) comprises performing a wave soldering, a spraying, a plating or an dipping operation.

17. A multi-layered substrate, at least comprising:
a lamination structure having at least a through-hole, wherein the through-hole passes through and links up with the surfaces of the lamination structure;
a first mask layer formed on one surface of the lamination structure, wherein the first mask layer has at least a first opening;
a second mask layer formed on another surface of the lamination structure, wherein the second mask layer has at least a second opening; and
a vertical routing structure comprising a conductive rod and a conductive layer, wherein the conductive rod occupies the interior of the through-hole and the ends of the conductive rod completely fill the first opening and the second opening respectively, and the conductive layer occupies the space between the interior surface of the through-hole and the conductive rod.

18. The multi-layered substrate of claim 17, wherein the second opening has a diameter greater than the through-hole.

19. The multi-layered substrate of claim 17, wherein the conductive layer further extends into the peripheral surface of the second opening of the second mask layer.

20. The multi-layered substrate of claim 17, wherein one end of the conductive rod serves as a bump, a pre-solder block or a contact.

21. The multi-layered substrate of claim 17, wherein the substrate furthermore comprises a bump attached to one end of the conductive rod.

22. The multi-layered substrate of claim 17, wherein the substrate furthermore comprises a pre-solder block attached to one end of the conductive rod.

23. The multi-layered substrate of claim 17, wherein the substrate furthermore comprises a solder ball attached to one end of the conductive rod.

24. The multi-layered substrate of claim 17, wherein the lamination structure furthermore comprises at least a buried circuit layer that connects electrically with the conductive layer.
